(19) United States
(12) Patent Application Publication
(10) Pub. No.: US 2025/0146876 A1
(43) Pub. Date: May 8, 2025

(54) BOLOMETER PIXEL AND BOLOMETER ARRAY

(71) Applicant: SAMSUNG ELECTRONICS CO., LTD., Suwon-si (KR)

(72) Inventors: Won Taek SEO, Suwon-si (KR); Anton SOFRONOV, Suwon-si (KR); Se Yoon KIM, Suwon-si (KR); Byong Gwon SONG, Suwon-si (KR); Jang Woo YOU, Suwon-si (KR); Du Hyun LEE, Suwon-si (KR)

(73) Assignee: SAMSUNG ELECTRONICS CO., LTD., Suwon-si (KR)

(21) Appl. No.: 18/614,301

(22) Filed: Mar. 22, 2024

(30) Foreign Application Priority Data
Nov. 6, 2023 (KR) 10-2023-0151536

(51) Int. Cl. G01J 5/0806; G01J 5/08; G01J 5/20

(52) U.S. Cl. CPC G01J 5/0806; G01J 5/0814; G01J 5/20; G01J 2005/202

(57) ABSTRACT

The present disclosure relates to a bolometer pixel and a bolometer array. The bolometer pixel includes: a substrate; an absorber configured to absorb incoming light in a predetermined wavelength range and having a central absorbent body that floats above the substrate by supports; and a reflector having a reflective layer provided on the substrate to reflect light incident on the substrate, and a pattern layer provided on the reflective layer to have lens power to concentrate the incident light onto the central absorbent body.

### CROSS-REFERENCE TO RELATED APPLICATION(S)

This application claims priority from Korean Patent Application No. 10-2023-0151536, filed on Nov. 6, 2023, in the Korean Intellectual Property Office, the disclosure of which is incorporated herein by reference in its entirety.

### BACKGROUND

### 1. Field

Apparatuses and methods consistent with example embodiments relate to a bolometer for converting incoming light energy in a predetermined wavelength range into heat energy and outputting the heat energy to generate image data.

### 2. Description of the Related Art

A bolometer may measure radiant energy emanating from an object, and particularly the quantity of infrared (IR) radiation emitted by the object. The bolometer converts incoming light energy in a predetermined wavelength range into heat energy, and outputs the heat energy to generate image data.

Multiple bolometers may be arranged in units of pixels to form a bolometer array. In order to acquire an accurate thermal image, it is important to reduce interference noise (cross-talk) among bolometer pixels and increase radiant energy absorption efficiency of each bolometer pixel. Here, cross-talk refers to a type of noise which is caused when incident light on a pixel leaks into a neighboring pixel and interferes with a signal value of the neighboring pixel.

In particular, as the incident angle of light on the bolometer pixel increases, light reflected from the substrate may easily travel to neighboring bolometer pixels, such that interference noise may increase. In addition, there is also a problem in effectively absorbing light energy by the absorption layer of the bolometer pixel.

The problem intensifies as the bolometer pixel becomes smaller in size, posing a significant hurdle that needs resolution for future applications of high-resolution thermal imaging cameras.

### SUMMARY

Example embodiments address at least the above problems and/or disadvantages and other disadvantages not described above. Also, the example embodiments are not required to overcome the disadvantages described above, and may not overcome any of the problems described above.

According to an aspect of the present disclosure, there is provided a bolometer pixel including: a substrate; an absorber configured to absorb incoming light in a predetermined wavelength range and having a central absorbent body that floats above the substrate by supports; and a reflector having a reflective layer formed on the substrate so as to reflect light incident on the substrate, and a pattern layer formed on the reflective layer so as to have lens power to concentrate the incident light onto the central absorbent body.

According to another aspect of the present disclosure, there is provided a bolometer array including: bolometer pixels each arranged in a structure including a substrate, an absorber configured to absorb incoming light in a predetermined wavelength range and having a central absorbent body that floats above the substrate by supports, and a reflector having a reflective layer formed on the substrate so as to reflect light incident on the substrate, and a pattern layer formed on the reflective layer so as to have lens power to concentrate the incident light onto the central absorbent body; and partition walls disposed between the bolometer pixels so as to block light that leaks from the respective bolometer pixels.

In one embodiment, the pattern layer may be formed as a zone plate with transparent rings and opaque rings that are alternately arranged in a concentric form, wherein a radius m from a center, at which the zone plate switches from the opaque ring to the transparent ring, may be given by the following Equation,

$${r}_{h} = \sqrt{h λ f + \frac{1}{4} {h}^{2} {λ}^{2}} ,$$

wherein λ may denote a wavelength, f may denote a focal length, and h may denote an integer.

In another embodiment, the pattern layer may be formed as a Fresnel lens, wherein a height z(r) with respect to a radius r from a center may be given by the following Equation,

$$z ( r ) = - \frac{1}{n} ( \sqrt{{r}^{2} + {f}^{2}} ) - \frac{λ}{n} h ,$$

wherein λ may denote a wavelength, n may denote a refractive index of the pattern layer, f may denote a focal length, and h may denote an integer.

In another embodiment, the pattern layer may be formed as a meta-lens having a meta-surface, wherein in a one-dimensional system along an x-axis of the meta-surface, a phase gradient do/dx may be set to have a target reflection angle of light with respect to an incident angle of light, by the following Equation,

$$sin {θ}_{r} - sin {θ}_{i} = \frac{λ}{2 π {n}_{i}} \frac{d ϕ}{dx} ,$$

wherein λ may denote a wavelength, n; may denote a refractive index of media on the meta-surface, θᵢ may denote the incident angle of light, and θᵣ may denote the reflection angle of light.

In another embodiment, the pattern layer may be formed as a circular symmetrical freeform, wherein the pattern layer may have a phase profile φ(r) which is set to meet target conditions according to a radius r from a center, and a height z(r) may be given by the following Equations according to the set phase profile φ(r),

$$ϕ ( r ) = 2 π \times \frac{z ( r )}{λ / n} .$$

$$z ( r ) = {a}_{0} + {a}_{1} {r}^{1} + {a}_{2} {r}^{2} + {a}_{3} {r}^{3} + … + {a}_{h} {r}^{h} ,$$

wherein λ may denote a wavelength, n may denote a refractive index of the pattern layer, and an may denote a polynomial coefficient.

In another embodiment, the pattern layer may be formed as an asymmetric freeform, wherein the pattern layer may have a phase profile φ(x, y) which is set to meet target conditions according to coordinates on an X-Y plane, and a height z(x, y) may be given by the following Equations according to the set phase profile φ(x, y),

$$ϕ ( x , y ) = 2 π \times \frac{z ( x , t )}{λ / n} ,$$

$$z ( x , y ) = {a}_{00} {x}^{0} {y}^{0} + {a}_{01} {x}^{0} {y}^{1} + {a}_{02} {x}^{0} {y}^{2} + {a}_{03} {x}^{0} {y}^{3} + … + {a}_{10} {x}^{1} {y}^{0} + {a}_{11} {x}^{1} {y}^{1} + {a}_{12} {x}^{1} {y}^{2} + {a}_{13} {x}^{1} {y}^{3} + … + {a}_{20} {x}^{2} {y}^{0} + {a}_{21} {x}^{2} {y}^{1} + {a}_{22} {x}^{2} {y}^{2} + {a}_{23} {x}^{2} {y}^{3} + … + {a}_{30} {x}^{3} {y}^{0} + {a}_{31} {x}^{3} {y}^{1} + {a}_{32} {x}^{3} {y}^{2} + {a}_{33} {x}^{3} {y}^{3} + … + {a}_{hh} {x}^{h} {y}^{h} ,$$

wherein λ may denote a wavelength, n may denote a refractive index of the pattern layer, and aₕₕ may denote a polynomial coefficient.

In one embodiment, a reflective surface of the reflective layer may be flat and in contact with the pattern layer.

In another embodiment, a reflective surface of the reflective layer may be in contact the pattern layer and may be curved away from the pattern layer. In this case, by defining a distance between a center of the absorber and the reflective surface as d, a curve radius of the reflective surface may be set to a value between 1.8 d to 32 d.

The reflective surface may be formed as a single layer or multiple layers of materials with different refractive indices.

The reflective surface may be formed as multiple layers of materials with different refractive indices, wherein the pattern layer may be disposed between the multiple layers of the reflective layer.

### BRIEF DESCRIPTION OF THE DRAWINGS

The above and/or other aspects will be more apparent by describing certain example embodiments, with reference to the accompanying drawings, in which:

FIG. 1 is a perspective view of a bolometer pixel according to embodiments of the present disclosure;

FIG. 2 is a cross-sectional view of the bolometer pixel illustrated in FIG. 1 according to embodiments of the present disclosure;

FIG. 3 is a cross-sectional view illustrating an example of a pattern layer in the form of a Fresnel lens according to embodiments of the present disclosure;

FIG. 4 is a cross-sectional view illustrating an example of a pattern layer in the form of a meta-lens according to embodiments of the present disclosure;

FIG. 5 is a perspective view illustrating an example of a meta-lens according to embodiments of the present disclosure;

FIG. 6 is a diagram explaining a relationship between an incident angle and a reflection angle of light;

FIG. 7 is a cross-sectional view illustrating an example of a pattern layer in the form of a freeform according to embodiments of the present disclosure;

FIG. 8 is a cross-sectional view illustrating an example of a reflective surface having a curved shape according to embodiments of the present disclosure;

FIG. 9 is a cross-sectional view illustrating an example of a reflective layer formed in a multi-layer structure according to embodiments of the present disclosure;

FIG. 10 is a cross-sectional view illustrating an example of a pattern layer disposed between multiple layers of a reflective layer according to embodiments of the present disclosure;

FIG. 11 is a cross-sectional view of a bolometer array according to embodiments of the present disclosure;

FIG. 12 is a plan view of the bolometer array shown in FIG. 11 according to embodiments of the present disclosure; and

FIG. 13 is a diagram of an electronic device according to embodiments of the present disclosure.

### DETAILED DESCRIPTION

Example embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the example embodiments. However, it is apparent that the example embodiments can be practiced without those specifically defined matters. Also, well-known functions or constructions are not described in detail since they would obscure the description with unnecessary detail.

It will be understood that, although the terms, “first,” “second,” etc., may be used herein to describe various elements, these elements should not be limited by these terms. These terms are only used to distinguish one element from another. Any references to singular may include plural unless expressly stated otherwise.

In addition, unless explicitly described to the contrary, an expression such as “comprising” or “including” will be understood to imply the inclusion of stated elements but not the exclusion of any other elements. Also, the terms, such as “unit” or “module,” etc., should be understood as a unit that performs at least one function or operation and that may be embodied as hardware, software, or a combination thereof.

Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, all of a, b, and c, or any variations of the aforementioned examples.

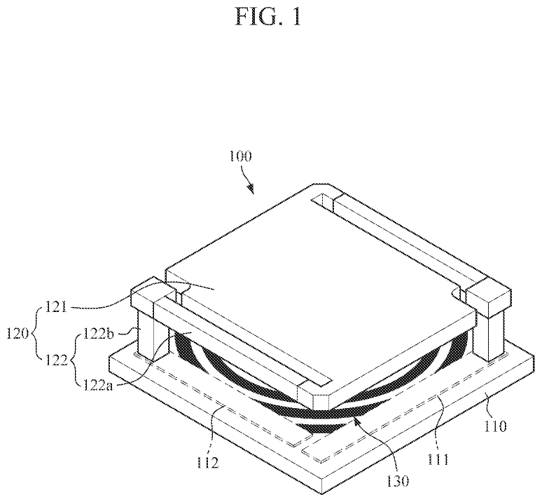

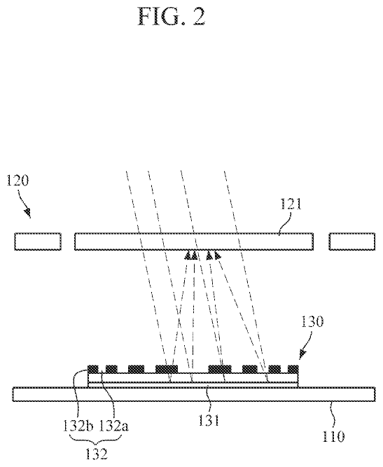

FIG. 1 is a perspective view of a bolometer pixel according to an embodiment of the present disclosure. FIG. 2 is a cross-sectional view of the bolometer pixel illustrated in FIG. 1.

Referring to FIGS. 1 and 2, a bolometer pixel 100 according to an embodiment of the present disclosure includes a substrate 110, an absorber 120, and a reflector 130.

A row electrode 111 and a column electrode 112 may be formed on the substrate 110. The row electrode 111 and the column electrode 112 may be in the form of strips and arranged orthogonal to each other.

The row electrode 111 and the column electrode 112 may be covered with a protective layer. The protective layer may include an insulating material, such as silicon dioxide (SiO₂), to protect and insulate the lower electrode 111 and the column electrode 112. The substrate 110 may be made of a material such as silicon and the like.

The row electrode 111 and the column electrode 112 may be electrically connected to a resistance layer in the absorber 120 through supports 122. The row electrode 111 and the column electrode 112 may apply a bias voltage so that a change in current due to a change in resistance of the resistance layer may be detected by a Read-Out Integrated Circuit (ROIC).

The absorber 120 may absorb incoming light in a predetermined wavelength range. The absorber 120 may have a resistance layer, which may be formed within the absorber 120 or laminated onto an absorption layer of the absorber 120. The absorber 120 may be made of Titanium Nitride (TiN) with high heat absorption rate.

Light energy absorbed by the absorber 120 is converted into heat energy, thereby raising temperature of the resistance layer. A resistance value of the resistance layer may change with a temperature change due to the heat energy absorbed by the absorber 120. The resistance layer may include amorphous Silicon (a-Si) or polycrystalline silicon, or the like.

A central absorbent body 121 of the absorber 120 may float above the substrate 110 by the supports 122. The central absorbent body 121 may not be in direct contact with the substrate 110 but instead may be supported and positioned above it by the supports 122 with a gap or separation between the central absorbent body 121 and the substrate 110. Each support 122 may include a supporting arm 122a and a leg 122b. The supporting arms 122a may extend from diagonal corners of the central absorbent body 121 and spaced apart from both sides of the central absorbent body 121.

The supporting arms 122a, except the portions connected to the central absorbent body 121, may have a uniform width and may be evenly spaced apart from both sides of the central absorbent body 121 by a predetermined distance. The supporting arms 122a may be made of the same material as the central absorbent body 121. The supporting arms 122a may electrically connect the resistance layer to the legs 122b.

The legs 122b may protrude from the row electrode 111 and the column electrode 112 and may be connected to the extended ends of the supporting arms 122a, thereby allowing the central absorbent body 121 to float above the substrate 110. Like the supporting arms 122a, the legs 122b may also be made of the same material as the central absorbent body 121. The legs 122b may allow the central absorbent body 121 to float a distance, corresponding to one quarter of an incident wavelength (2), from a reflective layer 131 of the substrate 110.

The reflector 130 may have a reflective layer 131 and a pattern layer 132. The reflective layer 131 may be formed on the substrate 110 to reflect light incident on the substrate 110. The reflective layer 131 may be formed on a surface of the substrate 110 that faces the central absorbent body 121 of the absorber 120. The reflective layer 131 may reflect light, incident from the outside, to the central absorbent body 121 through the pattern layer 132.

For example, a reflective surface of the reflective layer 131 may be implemented as a flat surface in contact with the pattern layer 132. The reflective layer 131 may be formed as a single layer. The reflective layer 131 may be formed with a uniform and consistent thickness on the substrate 110 by deposition and the like. The reflective layer 131 may be made of various metal materials with a predetermined reflectivity.

The pattern layer 132 may be formed on the reflective layer 131 to have lens power to concentrate the incident light onto the central absorbent body 121. The light incident from the outside may pass through the pattern layer 132 to be reflected by the reflective layer 131, and then may pass through the pattern layer 132 again. The incident light passes through the pattern layer 132 twice. This dual passage through the patent layer 132 may double the effective lens power and increase the concentration of the light onto the central absorbent body 121 of the absorber 120.

As described above, the reflector 130 ensures that even with an increased incident angle of light entering the bolometer pixel 100, the reflector 130 concentrates light onto the central absorbent body 121 of the absorber 120, such that light absorption efficiency of the absorber 120 may increase, and interference noise (cross-talk) with other neighboring pixels may be reduced.

For example, the pattern layer 132 may be in the form of a zone plate that utilizes diffraction to focus or manipulate light, for example, using a series of concentric rings with alternating transparent and opaque zones. The transparent zones may allow light to pass through, while the opaque zones may block or diffract the light. In some embodiments, the zone plate may include transparent rings 132a and opaque rings 132b that are alternately arranged in a concentric form. The transparent rings 132a may be made of transparent plastic, glass, and the like. The opaque rings 132b may be made of opaque metal and the like.

Light hitting the zone plate is diffracted around the opaque ring 132b. Here, the transparent rings 132a and the opaque rings 132b may be spaced so that the diffracted light constructively interferes at the desired focus.

A radius m from the center, at which the zone plate switches from the opaque ring 132b to the transparent ring 132a, may be given by the following Equation 1.

$${r}_{h} = \sqrt{h λ f + \frac{1}{4} {h}^{2} {λ}^{2}} , \qquad [ Equation 1 ]$$

wherein λ denotes a wavelength, f denotes a focal length, and h denotes an integer.

As described above, the pattern layer 132 in the form of a zone plate may concentrate light onto the central absorbent body 121 of the absorber 120, thereby increasing light absorption efficiency of the absorber 120 and reducing interference noise (cross-talk) with other neighboring pixels.

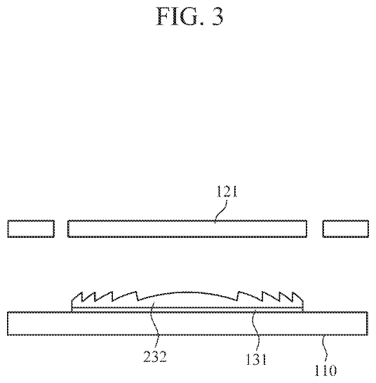

FIG. 3 is a cross-sectional view illustrating an example of a pattern layer in the form of a Fresnel lens.

Referring to FIG. 3, the pattern layer 232 may be in the form of a Fresnel lens. The Fresnel lens is a lens which is divided into several bands to reduce thickness, and each band has a prism function to reduce aberration. The Fresnel lens may be used to concentrate light by dividing a continuous surface of the lens into a set of surfaces of the same curvature, with stepwise discontinuities between them. The Fresnel lens may be made of polymethyl methacrylate (PMMA) and the like.

A height z(r) with respect to a radius r from the center of the Fresnel lens may be given by the following Equation 2.

$$z ( r ) = - \frac{1}{n} ( \sqrt{{r}^{2} + {f}^{2}} ) - \frac{λ}{n} h , \qquad [ Equation 2 ]$$

wherein λ denotes a wavelength, n denotes a refractive index of the pattern layer, f denotes a focal length, and h denotes an integer.

As described above, the pattern layer 232 in the form of a Fresnel lens may concentrate light onto the central absorbent body 121 of the absorber 120, thereby increasing light absorption efficiency of the absorber 120 and reducing interference noise (cross-talk) with other neighboring pixels.

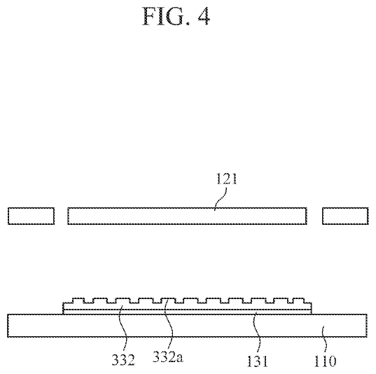

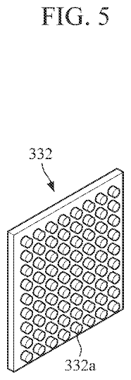

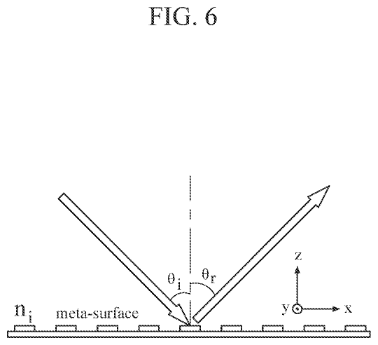

FIG. 4 is a cross-sectional view illustrating an example of a pattern layer in the form of a meta-lens. FIG. 5 is a perspective view illustrating an example of a meta-lens. FIG. 6 is a diagram explaining a relationship between an incident angle and a reflection angle of light.

Referring to FIGS. 4 and 5, the pattern layer 332 may be in the form of a meta-lens having a meta-surface 332a. The meta-lens, having the meta-surface 332a with nano-sized particles arranged periodically, may be used to concentrate light. The nanoparticles of the meta-lens may be in the form of nanorod, nanopillar, and the like.

The meta-lens provides focus control by changing the phase of particles arranged on the meta-surface 332a. The meta-lens may be made of a non-metallic dielectric material, such as titanium dioxide (TiO₂), gallium nitride (GaN).

As illustrated in FIG. 6, in a one-dimensional system along an x-axis of the meta-surface 332a, a phase gradient do/dx is set to have a target reflection angle of light with respect to an incident angle of light, by the following Equation.

$$sin {θ}_{r} - sin {θ}_{i} = \frac{λ}{2 π {n}_{i}} \frac{d ϕ}{dx} , \qquad [ Equation 3 ]$$

wherein λ denotes a wavelength, nᵢ denotes a refractive index of media on the meta-surface, θᵢ denotes the incident angle of light, and Or denotes the reflection angle of light.

The phase profile of the meta-surface 332a may be set based on a focal position, the number of focal points, focal shape, and the like. The meta-surface 332a may be designed by various known optical design programs according to the set phase profile.

By using a meta-surface pattern, the same operation and effect as those of the zone plate and Fresnel lens may be achieved. Further, by using a meta-surface pattern, the same operation and effect as those of a circular symmetrical freeform and asymmetrical freeform, which will be described below, may be achieved.

The phase of the meta-surface pattern may be controlled so that the meta-surface pattern may function in the same manner as the zone plate, Fresnel lens, circular symmetrical freeform, and asymmetrical freeform. The meta-surface pattern, achieving the same operation and reflection effect as a physical curve radius, may be formed on a flat surface. Alternatively, the meta-surface pattern may be formed on a curved surface, such that the curved surface and the meta-surface pattern may act simultaneously to achieve the same operation and reflection effect as the physical curve radius.

As described above, the pattern layer 332 in the form of a meta-lens may concentrate light onto the central absorbent body 121 of the absorber 120, thereby increasing light absorption efficiency of the absorber 120 and reducing interference noise (cross-talk) with other neighboring pixels.

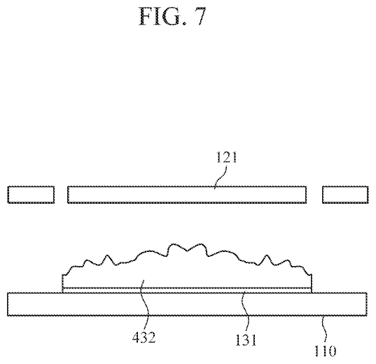

FIG. 7 is a cross-sectional view illustrating an example of a pattern layer in the form of a freeform.

Referring to FIG. 7, a pattern layer 432 may be in the form of a circular symmetrical freeform. The pattern layer 432 has a phase profile φ(r) which is set to meet target conditions according to the radius r from the center, and the height z(r) may be given by the following Equation 4 according to the set phase profile φ(r).

The phase profile φ(r) of the pattern layer 432 may be set based on a focal position, the number of focal points, focal shape, and the like. A value of z(r) is obtained by a relational expression with the phase φ(r) according to the radius r, and then is substituted into the polynomial equation of z(r), to obtain a polynomial coefficient. Accordingly, the height z(r) with respect to the radius r on the pattern layer 432 may be obtained.

$$ϕ ( r ) = 2 π \times \frac{z ( r )}{λ / n} , \qquad [ Equation 4 ]$$

$$z ( r ) = {a}_{0} + {a}_{1} {r}^{1} + {a}_{2} {r}^{2} + {a}_{3} {r}^{3} + … + {a}_{h} {r}^{h} ,$$

wherein λ denotes a wavelength, n denotes a refractive index of the pattern layer, and an denotes a polynomial coefficient.

In another example, the pattern layer 432 may be in the form of an asymmetrical freeform. The pattern layer 432 has a phase profile φ(x, y) which is set to meet target conditions according to coordinates on the X-Y plane, and a height z(x, y) may be given by the following Equation 5 according to the set phase profile φ(x, y).

The phase profile φ(x, y) of the pattern layer 432 may be set based on a focal position, the number of focal points, focal shape, and the like. A value of z(x, y) is obtained by a relational expression with the phase φ(x, y) according to the (x, y) coordinates, and then is substituted into the polynomial equation of z(x, y), to obtain a polynomial coefficient. Accordingly, the height z(x, y) with respect to the (x, y) coordinates on the pattern layer 432 may be obtained.

$$ϕ ( x , y ) = 2 π \times \frac{z ( x , y )}{λ / n} , \qquad [ Equation 5 ]$$

$$z ( x , y ) = {a}_{00} {x}^{0} {y}^{0} + {a}_{01} {x}^{0} {y}^{1} + {a}_{02} {x}^{0} {y}^{2} + {a}_{03} {x}^{0} {y}^{3} + … + {a}_{10} {x}^{1} {y}^{0} + {a}_{11} {x}^{1} {y}^{1} + {a}_{12} {x}^{1} {y}^{2} + {a}_{13} {x}^{1} {y}^{3} + … + {a}_{20} {x}^{2} {y}^{0} + {a}_{21} {x}^{2} {y}^{1} + {a}_{22} {x}^{2} {y}^{2} + {a}_{23} {x}^{2} {y}^{3} + … + {a}_{30} {x}^{3} {y}^{0} + {a}_{31} {x}^{3} {y}^{1} + {a}_{32} {x}^{3} {y}^{2} + {a}_{33} {x}^{3} {y}^{3} + … + {a}_{hh} {x}^{h} {y}^{h} ,$$

wherein λ denotes a wavelength, n denotes a refractive index of the pattern layer, and aₕₕ denotes a polynomial coefficient.

As described above, the pattern layer 432 in the form of a freeform may concentrate light onto the central absorbent body 121 of the absorber 120, thereby increasing light absorption efficiency of the absorber 120 and reducing interference noise (cross-talk) with other neighboring pixels.

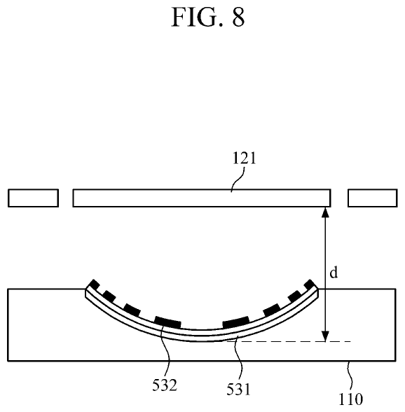

FIG. 8 is a cross-sectional view illustrating an example of a reflective surface which is a curved surface.

Referring to FIG. 8, a reflective surface of a reflective layer 531 may be implemented as a curved surface that is in contact with a pattern layer 532. The reflective surface of the reflective layer 531 may be curved away from the pattern layer 532, forming a concave shape in a direction away from the pattern layer 532. If using the pattern layer 532 alone is not sufficient such that light control is limited, the reflective layer 531 having a curved reflective surface may be used to optimize light control for increasing light absorption efficiency and reducing interference noise. As shown in the above examples, the pattern layer 532 may be formed as the zone plate, as well as the Fresnel lens, meta lens, freeform, and the like.

The reflective layer 531 may be formed with a uniform and consistent thickness. By defining a distance between the center of the absorber 120 and the reflective surface as d, a curve radius of the reflective surface may be set to a value between 1.8 d to 32 d.

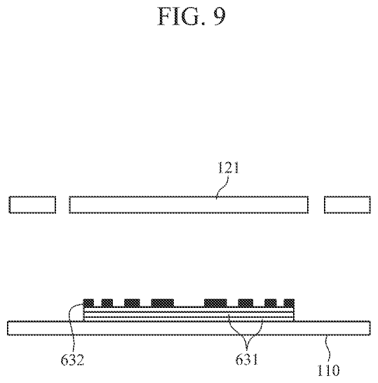

FIG. 9 is a cross-sectional view illustrating an example of a reflective layer formed in a multi-layer structure.

Referring to FIG. 9, a reflective layer 631 may be formed with multiple layers of materials having different refractive indices. For example, the reflective layer 631 may have a distributed Bragg reflector structure in which dielectrics with different refractive indices are stacked. In another example, the reflective layer 631 may have a structure in which metals with different refractive indices are stacked.

In yet another example, the reflective layer 631 may have a structure in which metals and dielectrics are stacked. Here, the dielectric layer may be disposed closer to the pattern layer 632 than the metallic layer. As shown in the above examples, the pattern layer 632 may be formed as the zone plate, as well as the Fresnel lens, meta lens, freeform, and the like.

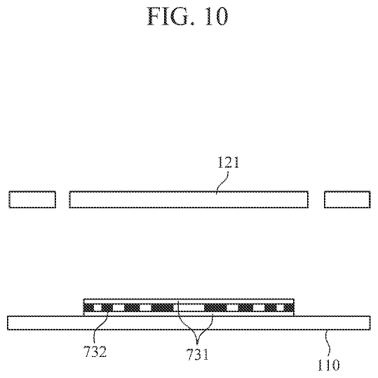

FIG. 10 is a cross-sectional view illustrating an example of a pattern layer disposed between multiple layers of a reflective layer.

Referring to FIG. 10, a reflective layer 731 may be formed with multiple layers of materials having different refractive indices, and the pattern layer 732 may be disposed between the multiple layers of the reflective layer 731. As shown in the above examples, the reflective layer 731 may be formed in a structure in which dielectrics with different refractive indices are stacked or a dielectric layer is disposed closer to the pattern layer 732 than a metallic layer. The pattern layer 732 may be formed as the zone plate, as well as the Fresnel lens, meta lens, freeform, and the like.

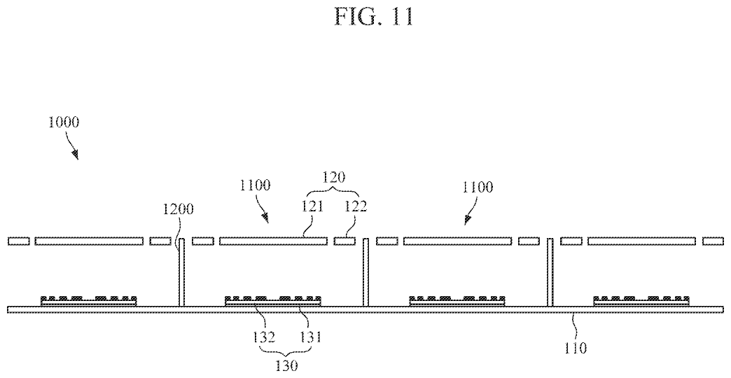

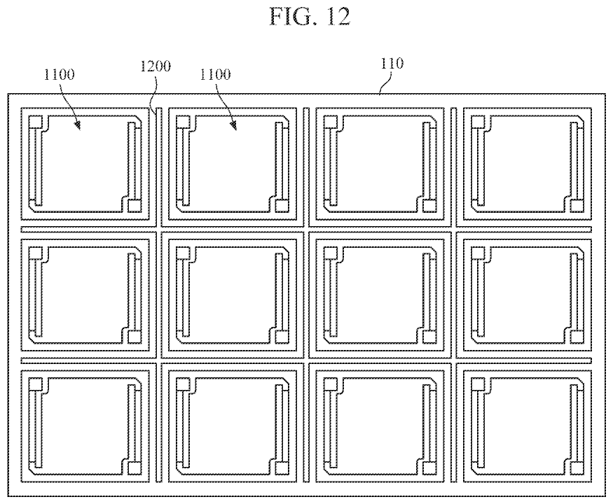

FIG. 11 is a cross-sectional view of a bolometer array according to an embodiment of the present disclosure. FIG. 12 is a plan view of the bolometer array shown in FIG. 11.

Referring to FIGS. 11 and 12, a bolometer array 1000 according to an embodiment of the present disclosure may include bolometer pixels 1100 and partition walls 1200.

The bolometer pixels 1100 may be formed similarly to the bolometer pixel 100 described above. The respective bolometer pixels 1100 may be arranged in a structure including: the substrate 110; the absorber 120 configured to absorb incoming light in a predetermined wavelength range and having the central absorbent body 121 that floats above the substrate 110 by the supports 122; and the reflector 130 having the reflective layer 131 formed on the substrate 110 so as to reflect light incident on the substrate 110, and the pattern layer 132 formed on the reflective layer 131 so as to have lens power to concentrate the incident light onto the central absorbent body 121.

The reflective layer 131 and the pattern layer 132 may be formed in various structures as shown in the above examples in addition to this example. All the substrates 110 of the bolometer pixels 1100 may be connected to form a single substrate.

The partition walls 1200 may be disposed between the bolometer pixels 1100 so as to block light that leaks from the respective bolometer pixels 1100. The partition walls 1200 may greatly reduce interference noise between the bolometer pixels 1100.

The partition walls 1200 may be connected in a mesh arrangement to surround the respective bolometer pixels 1100. The partition wall 1200 has a first end connected to a substrate 110 to be supported thereby, and a second end disposed between the central absorption bodies 121, thereby blocking interference noise between the bolometer pixels 1100. The partition walls 1200 may be formed with a uniform thickness. The partition wall 1200 may be made of various materials with high reflectivity to minimize optical loss.

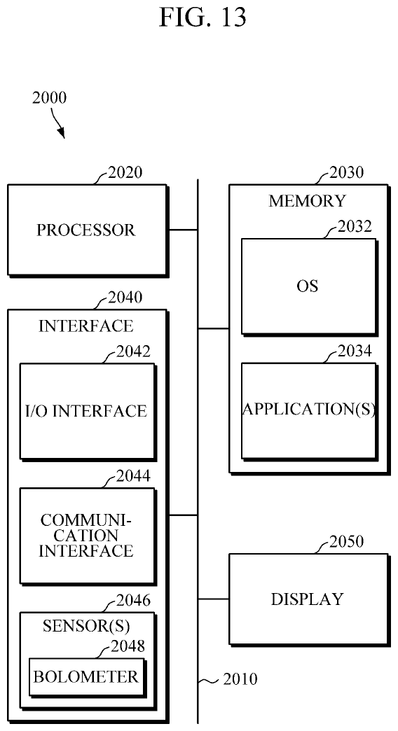

FIG. 13 is a diagram of an electronic device 2000 including a bolometer according to embodiments of the present disclosure. FIG. 13 is for illustration only, and other embodiments of the electronic device 2000 could be used without departing from the scope of this disclosure.

The electronic device 2000 includes a bus 2010, a processor 2020, a memory 2030, an interface 2040, and a display 2050.

The bus 2010 includes a circuit for connecting the components 2020 to 2050 with one another. The bus 2010 functions as a communication system for transferring data between the components 2020 to 2050 or between electronic devices.

The processor 2020 includes one or more of a central processing unit (CPU), a graphics processor unit (GPU), an accelerated processing unit (APU), a many integrated core (MIC), a field-programmable gate array (FPGA), or a digital signal processor (DSP). The processor 2020 is able to perform control of any one or any combination of the other components of the device 2000, and/or perform an operation or data processing relating to communication. The processor 2020 executes one or more programs stored in the memory 2030.

The memory 2030 may include a volatile and/or non-volatile memory. The memory 2030 stores information, such as one or more of commands, data, programs (one or more instructions), and applications 2034, etc., which are related to at least one other component of the electronic device 2000 and for driving and controlling the electronic device 2000. For example, commands and/or data may formulate an operating system (OS) 2032. Information stored in the memory 2030 may be executed by the processor 2020.

The display 2050 includes, for example, a liquid crystal display (LCD), a light emitting diode (LED) display, an organic light emitting diode (OLED) display, a quantum-dot light emitting diode (QLED) display, a microelectromechanical systems (MEMS) display, or an electronic paper display. The display 2050 can also be a depth-aware display, such as a multi-focal display. The display 2050 is able to present, for example, various contents, such as text, images, videos, icons, and symbols.

The interface 2040 includes input/output (I/O) interface 2042, communication interface 2044, and/or one or more sensors 2046. The I/O interface 2042 serves as an interface that can, for example, transfer commands and/or data between a user and/or other external devices and other component(s) of the electronic device 2000. The I/O interface 2042 can also include any one or any combination of a microphone, a keyboard, a mouse, and one or more buttons for touch input.

The sensor(s) 2046 can meter a physical quantity or detect an activation state of the electronic device 2000 and convert metered or detected information into an electrical signal. For example, the sensor(s) 2046 can include one or more cameras or other imaging sensors for capturing images of scenes. In particular, the sensors(s) 2046 may include a bolometer 2048. The bolometer 2048 may include the bolometer pixel 100 and the bolometer array 1000 illustrated in FIGS. 1-12. In addition, the sensor(s) 1046 can include a control circuit for controlling at least one of the sensors included herein. Any of these sensor(s) 1046 can be located within or coupled to the electronic device 2000.

The communication interface 2044, for example, is able to set up communication between the electronic device 2000 and an external electronic device. The communication interface 2044 can be a wired or wireless transceiver or any other component for transmitting and receiving signals.

The foregoing exemplary embodiments are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. A bolometer pixel comprising:
a substrate;
an absorber configured to absorb incoming light in a predetermined wavelength range and having a central absorbent body that floats above the substrate by supports; and
a reflector comprising a reflective layer provided on the substrate and configured to reflect light incident on the substrate, and a pattern layer provided on the reflective layer and configured to have lens power to concentrate the incident light onto the central absorbent body.

2. The bolometer pixel of claim 1, wherein the pattern layer comprises a zone plate with transparent rings and opaque rings that are alternately arranged in a concentric form,
wherein a radius rₕ from a center, at which the zone plate switches from the opaque ring to the transparent ring, is given by the following Equation,
$${r}_{h} = \sqrt{h λ f + \frac{1}{4} {h}^{2} {λ}^{2}} ,$$
wherein λ denotes a wavelength, f denotes a focal length, and h denotes an integer.

3. The bolometer pixel of claim 1, wherein the pattern layer is formed as a Fresnel lens,
wherein a height z(r) with respect to a radius r from a center is given by the following Equation,
$$z ( r ) = - \frac{1}{n} ( \sqrt{{r}^{2} + {f}^{2}} ) - \frac{λ}{n} h ,$$
wherein λ denotes a wavelength, n denotes a refractive index of the pattern layer, f denotes a focal length, and h denotes an integer.

4. The bolometer pixel of claim 1, wherein the pattern layer comprises a meta-lens having a meta-surface,
wherein in a one-dimensional system along an x-axis of the meta-surface, a phase gradient dφ/dx is set to have a target reflection angle of light with respect to an incident angle of light, by the following Equation,
$$sin {θ}_{r} - sin {θ}_{i} = \frac{λ}{2 π {n}_{i}} \frac{d ϕ}{dx} ,$$
wherein λ denotes a wavelength, nᵢ denotes a refractive index of media on the meta-surface, θᵢ denotes the incident angle of light, and θᵣ denotes the reflection angle of light.

5. The bolometer pixel of claim 1, wherein the pattern layer comprises a circular symmetrical freeform,
wherein the pattern layer has a phase profile φ(r) which is set to meet target conditions according to a radius r from a center, and a height z(r) is given by the following Equations according to the set phase profile φ(r),
$$ϕ ( r ) = 2 π \times \frac{z ( r )}{λ / n} ,$$
$$z ( r ) = {a}_{0} + {a}_{1} {r}^{1} + {a}_{2} {r}^{2} + {a}_{3} {r}^{3} + … + {a}_{h} {r}^{h} ,$$
wherein λ denotes a wavelength, n denotes a refractive index of the pattern layer, and aₕ denotes a polynomial coefficient.

6. The bolometer pixel of claim 1, wherein the pattern layer comprises an asymmetric freeform,
wherein the pattern layer has a phase profile φ(x, y) which is set to meet target conditions according to coordinates on an X-Y plane, and a height z(x, y) is given by the following Equations according to the set phase profile φ(x, y),
$$ϕ ( x , y ) = 2 π \times \frac{z ( x , y )}{λ / n} ,$$
$$z ( x , y ) = {a}_{00} {x}^{0} {y}^{0} + {a}_{01} {x}^{0} {y}^{1} + {a}_{02} {x}^{0} {y}^{2} + {a}_{03} {x}^{0} {y}^{3} + … + {a}_{10} {x}^{1} {y}^{0} + {a}_{11} {x}^{1} {y}^{1} + {a}_{12} {x}^{1} {y}^{2} + {a}_{13} {x}^{1} {y}^{3} + … + {a}_{20} {x}^{2} {y}^{0} + {a}_{21} {x}^{2} {y}^{1} + {a}_{22} {x}^{2} {y}^{2} + {a}_{23} {x}^{2} {y}^{3} + … + {a}_{30} {x}^{3} {y}^{0} + {a}_{31} {x}^{3} {y}^{1} + {a}_{32} {x}^{3} {y}^{2} + {a}_{33} {x}^{3} {y}^{3} + … + {a}_{hh} {x}^{h} {y}^{h} ,$$
wherein 2 denotes a wavelength, n denotes a refractive index of the pattern layer, and aₕₕ denotes a polynomial coefficient.

7. The bolometer pixel of claim 1, wherein a reflective surface of the reflective layer is flat and in contact with the pattern layer.

8. The bolometer pixel of claim 1, wherein a reflective surface of the reflective layer is in contact with the pattern layer and is curved away from the pattern layer.

9. The bolometer pixel of claim 1, wherein the reflective surface comprises multiple layers of materials with different refractive indices.

10. The bolometer pixel of claim 9, wherein the pattern layer is disposed between the multiple layers of the reflective layer.

11. A bolometer array comprising:
bolometer pixels provided in a structure comprising:
a substrate;
an absorber configured to absorb incoming light in a predetermined wavelength range and having a central absorbent body that floats above the substrate by supports; and
a reflector comprising a reflective layer provided on the substrate and configured to reflect light incident on the substrate, and a pattern layer provided on the reflective layer and configured to have lens power to concentrate the incident light onto the central absorbent body; and
partition walls disposed between the bolometer pixels to block light that leaks from the bolometer pixels.

12. The bolometer array of claim 11, wherein the pattern layer comprises a zone plate with transparent rings and opaque rings that are alternately arranged in a concentric form,
wherein a radius rₕ from a center, at which the zone plate switches from the opaque ring to the transparent ring, is given by the following Equation,
$${r}_{h} = \sqrt{h λ f + \frac{1}{4} {h}^{2} {λ}^{2}} ,$$
wherein λ denotes a wavelength, f denotes a focal length, and h denotes an integer.

13. The bolometer array of claim 11, wherein the pattern layer comprises a Fresnel lens,
wherein a height z(r) with respect to a radius r from a center is given by the following Equation,
$$z ( r ) = - \frac{1}{n} ( \sqrt{{r}^{2} + {f}^{2}} ) - \frac{λ}{n} h ,$$
wherein λ denotes a wavelength, n denotes a refractive index of the pattern layer, f denotes a focal length, and h denotes an integer.

14. The bolometer array of claim 11, wherein the pattern layer comprises a meta-lens having a meta-surface,
wherein in a one-dimensional system along an x-axis of the meta-surface, a phase gradient dφ/dx is set to have a target reflection angle of light with respect to an incident angle of light, by the following Equation,
$$sin {θ}_{r} - sin {θ}_{i} = \frac{λ}{2 π {n}_{i}} \frac{d ϕ}{dx} ,$$
wherein λ denotes a wavelength, nᵢ denotes a refractive index of media on the meta-surface, θᵢ denotes the incident angle of light, and θᵣ denotes the reflection angle of light.

15. The bolometer array of claim 11, wherein the pattern layer comprises a circular symmetrical freeform,
wherein the pattern layer has a phase profile φ(r) which is set to meet target conditions according to a radius r from a center, and a height z(r) is given by the following Equations according to the set phase profile φ(r),
$$ϕ ( r ) = 2 π \times \frac{z ( r )}{λ / n} ,$$
$$z ( r ) = {a}_{0} + {a}_{1} {r}^{1} + {a}_{2} {r}^{2} + {a}_{3} {r}^{3} + … + {a}_{h} {r}^{h} ,$$
wherein λ denotes a wavelength, n denotes a refractive index of the pattern layer, and aₕ denotes a polynomial coefficient.

16. The bolometer array of claim 11, wherein the pattern layer comprises an asymmetric freeform,
wherein the pattern layer has a phase profile φ(x, y) which is set to meet target conditions according to coordinates on an X-Y plane, and a height z(x, y) is given by the following Equations according to the set phase profile φ(x, y),
$$ϕ ( x , y ) = 2 π \times \frac{z ( x , y )}{λ / n} ,$$
$$z ( x , y ) = {a}_{00} {x}^{0} {y}^{0} + {a}_{01} {x}^{0} {y}^{1} + {a}_{02} {x}^{0} {y}^{2} + {a}_{03} {x}^{0} {y}^{3} + … + {a}_{10} {x}^{1} {y}^{0} + {a}_{11} {x}^{1} {y}^{1} + {a}_{12} {x}^{1} {y}^{2} + {a}_{13} {x}^{1} {y}^{3} + … + {a}_{20} {x}^{2} {y}^{0} + {a}_{21} {x}^{2} {y}^{1} + {a}_{22} {x}^{2} {y}^{2} + {a}_{23} {x}^{2} {y}^{3} + … + {a}_{30} {x}^{3} {y}^{0} + {a}_{31} {x}^{3} {y}^{1} + {a}_{32} {x}^{3} {y}^{2} + {a}_{33} {x}^{3} {y}^{3} + … + {a}_{hh} {x}^{h} {y}^{h} ,$$
wherein 2 denotes a wavelength, n denotes a refractive index of the pattern layer, and aₕₕ denotes a polynomial coefficient.

17. The bolometer array of claim 11, wherein a reflective surface of the reflective layer is flat and in contact with the pattern layer.

18. The bolometer array of claim 11, wherein a reflective surface of the reflective layer is in contact with the pattern layer and is curved away from the pattern layer.

19. The bolometer array of claim 11, wherein the reflective surface comprises multiple layers of materials with different refractive indices.

20. The bolometer array of claim 11, wherein the pattern layer is disposed between the multiple layers of the reflective layer.
